(19) United States
(12) Patent Application Publication
(10) Pub. No.: US 2026/0276700 A1
(43) Pub. Date: Sep. 17, 2026

(54) TEST CIRCUITRY FOR RING AMPLIFIER

(71) Applicant: TAIWAN SEMICONDUCTOR MANUFACTURING COMPANY LTD., HSINCHU (TW)

(72) Inventors: PO-YU LAI, HSINCHU (TW); MEI-CHEN CHUANG, PINGTUNG COUNTY (TW)

(21) Appl. No.: 19/080,974

(22) Filed: Mar. 17, 2025

(51) Int. Cl. G01R 31/28

(52) U.S. Cl. CPC G01R 31/287; G01R 31/2882

(57) ABSTRACT

A measuring circuit is provided, which includes a clock generator, a test circuit, and a trigger circuit. The clock generator is configured to convert an input clock signal into a plurality of clock signals, which are non-overlapping, and generate a counter signal. The test circuit is coupled to an output terminal of a ring amplifier and is configured to store electric charges from a load capacitance of the ring amplifier using a test capacitance. The trigger circuit is configured to generate a trigger signal for measuring an output voltage of the ring amplifier based on the counter signal.

### BACKGROUND

Ring amplifiers are a type of amplifier that has become popular in analog circuit design due to their high gain and efficiency. These qualities make them suitable for applications like data converters and signal processing systems. Their design includes a feedback loop that boosts their performance. Recent advancements in semiconductor technology have made it easier to integrate ring amplifiers into complex electronic systems, leading to improved functionality and smaller sizes.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1A is a schematic diagram of a test system for a ring amplifier in accordance with some embodiments of the present disclosure.

FIG. 1B is another schematic diagram of a test system for a ring amplifier in accordance with some embodiments of the present disclosure.

FIG. 2 is a schematic diagram of the clock generator 130 in accordance with the embodiments of FIGS. 1A and 1B.

FIG. 3 is a schematic diagram of the trigger circuit 140 in accordance with the embodiments of FIGS. 1A and 1B.

FIG. 4 is a waveform diagram of various signals within the test system in accordance with the embodiments of FIGS. 1A and 1B.

FIG. 5 is a waveform diagram of different clock signals in accordance with the embodiments of FIGS. 1A and 1B.

FIG. 6 is a waveform diagram illustrating the relationships between output voltage and transient waveform of the ring amplifier with respect to clock signals with different operating frequencies in accordance with some embodiments of the present disclosure.

FIG. 7 is a flowchart of a method for operating a measuring circuit for a ring amplifier in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

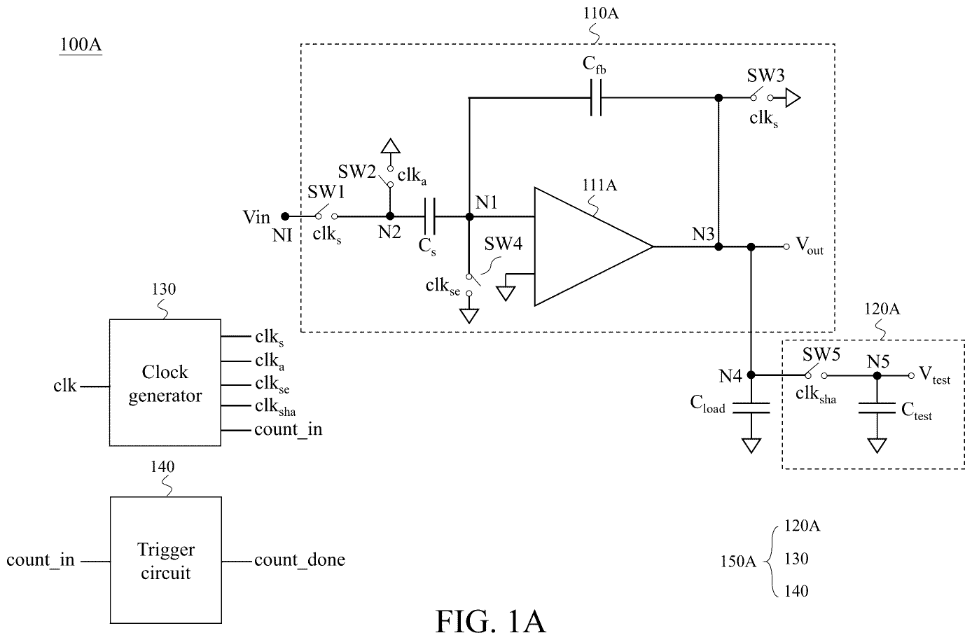

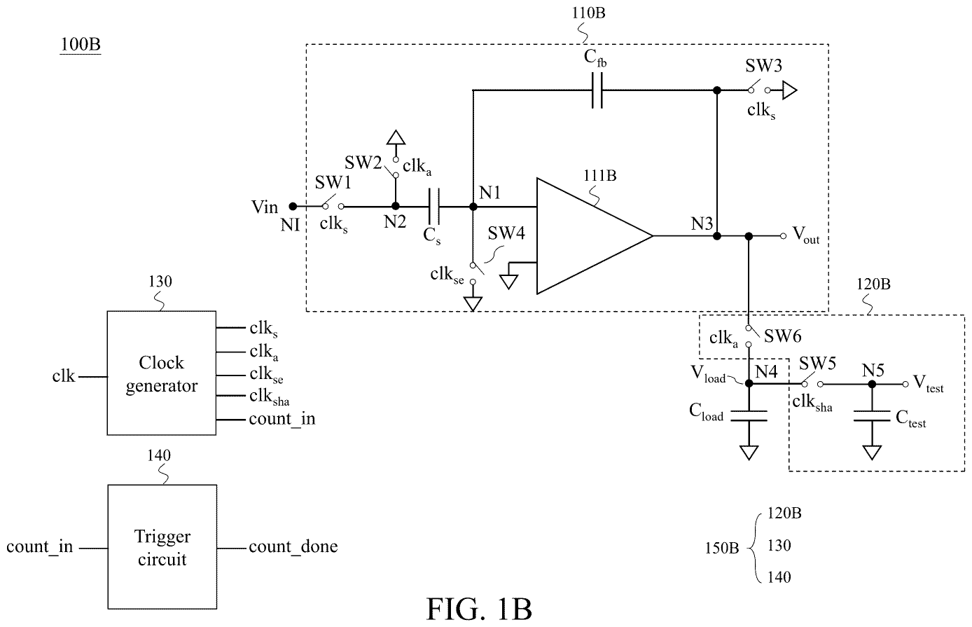

FIG. 1A is a schematic diagram of a test system for a ring amplifier in accordance with some embodiments of the present disclosure.

In some embodiments, the test system 100A includes a ring amplifier 110A, a test circuit 120A, a clock generator 130, and a trigger circuit 140, as depicted in FIG. 1A. The test system 100A may be designed for measuring the output voltage Vₒᵤₜ of the ring amplifier 110A using the test circuit 120A, the clock generator 130, and the trigger circuit 140. The test circuit 120A, clock generator 130, and trigger circuit 140 can be collectively regarded as a measuring circuit 150A. In some embodiments, the ring amplifier 110A may include an operational amplifier 111A, switches SW1 to SW4, a sampling capacitance Cₛ, and a feedback capacitance C_{fb}. Additionally, the operational amplifier 111A may be implemented using a discrete-time operational amplifier. The ring amplifier 110A may operate in a plurality of operational phases, such as a sampling phase, an amplification phase, and a sharing phase. A discrete-time operational amplifier processes signals at specific intervals, operating on sampled versions of the input signal. The signal is sampled and held at discrete time points, and the discrete-time operational amplifier processes these samples. In some embodiments, a discrete-time operational amplifier can be implemented using switched-capacitor circuits, where capacitors are charged and discharged at specific intervals controlled by a clock signal. This design allows precise control over the operation timing and is suitable for integration in digital systems. In some embodiments, a discrete-time operational amplifier is suitable for use in digital signal processing, data conversion (such as analog-to-digital converters), and systems where signal processing is synchronized with a clock signal.

In some embodiments, the operational amplifier 111A includes a first input terminal coupled to node N1, and a second input terminal coupled to the ground. The output terminal (e.g., node N3) of the operational amplifier 111A, which serves as the output terminal of the ring amplifier 110A, is coupled to the first input terminal through the feedback capacitance C_{fb}. Additionally, the switches SW1 to SW4 are controlled by respective clock signals clkₛ, clkₐ, clkₛ, and clkₛₑ, as depicted in FIG. 1A. In some embodiments, the clock signals clkₛ, clkₐ, and clkₛₑ may be used during the sampling phase, amplification phase, and sampling phase, respectively, the details of which will be described later. In some embodiments, the clock signal clkₛ is a delayed version of the clock signal clkₛₑ. Additionally, the clock signals clkₛ, clkₐ, and clkₛₕₐ are non-overlapping clock signals, indicating that their duties (e.g., high logic states) are non-overlapping.

In some embodiments, switch SW1, which is controlled by the clock signal clkₛ is coupled between an input node NI and node N2, indicating that switch SW1 is activated (e.g. short-circuited) in response to the clock signal clkₛ being in the high logic state, and is deactivated (e.g., open-circuited) in response to the clock signal clkₛ being in the low logic state. Switch SW2, which is controlled by the clock signal clkₐ, is coupled between node N2 and the ground, indicating that switch SW2 is activated (e.g. short-circuited) in response to the clock signal clkₐ being in the high logic state, and is deactivated (e.g., open-circuited) in response to the clock signal clkₐ being in the low logic state.

Additionally, a sampling capacitor Cₛ is coupled between nodes N1 and N2. Switch SW3, which is controlled by the clock signal clkₛ, is coupled between node N3 and the ground, indicating that switch SW3 is activated (e.g. short-circuited) in response to the clock signal clkₛ being in the high logic state, and is deactivated (e.g., open-circuited) in response to the clock signal clkₛ being in the low logic state. Switch SW4, which is controlled by the clock signal clkₛₑ, is coupled between node N1 and the ground, indicating that switch SW4 is activated (e.g. short-circuited) in response to the clock signal clkₛₑ being in the high logic state, and is deactivated (e.g., open-circuited) in response to the clock signal clkₛₑ being in the low logic state. The ring amplifier 110A can operate in its sampling phase, amplification phase, and sharing phase using the configurations with switches SW1 to SW4, sampling capacitance Cₛ, and feedback capacitance C_{fb}.

In some embodiments, the test circuit 120A is coupled to the output terminal (e.g., node N3) of the ring amplifier 110A to measure the output voltage Vₒᵤₜ of the ring amplifier 110A as the test voltage Vₜₑₛₜ, as depicted in FIG. 1A. For example, the test circuit 120A includes a test capacitance Cₜₑₛₜ and switch SW5. Additionally, the output terminal (e.g., node N3) of the ring amplifier 110A is coupled to a load capacitance C_{load}. The load capacitance C_{load} is coupled between node N4 and the ground, where nodes N3 and N4 can be referred to as the same node in FIG. 1A. Switch SW5, which is controlled by the clock signal clkₛₕₐ, is coupled between nodes N4 and N5. The test capacitance Cₜₑₛₜ is coupled between node N5 and the ground. In some embodiments, the test capacitance Cₜₑₛₜ is configured to store electric charges shared by the ring amplifier 110A in response to the clock signal clkₛₕₐ being in the high logic state, and thus the voltage potential stored in the test capacitance Cₜₑₛₜ may gradually increase until it reaches the maximum voltage amplitude (e.g., rail-to-rail swing) of the output voltage Vₒᵤₜ of the ring amplifier 110A. It should be noted that since the ring amplifier 110A is implemented using the discrete-time operational amplifier 111A, it does not operate in its sharing phase, so that nodes N3 and N4 can be electrically connected and collectively referred to as the same node.

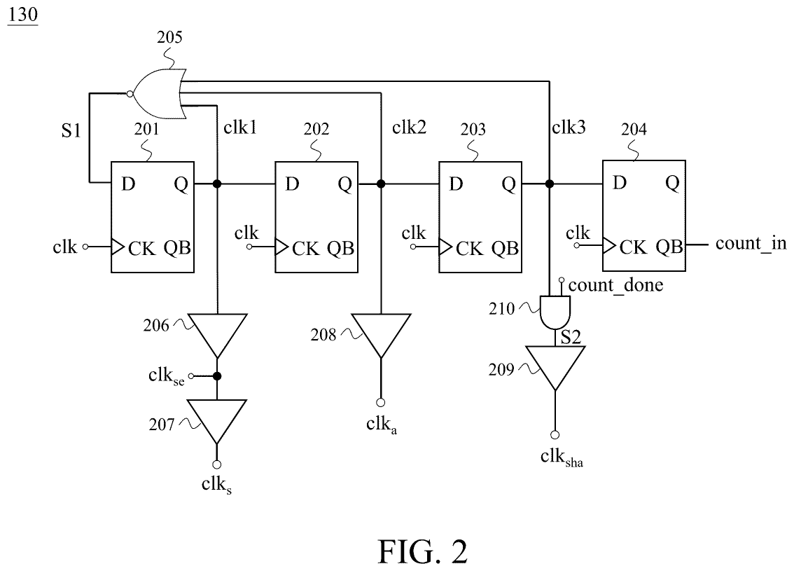

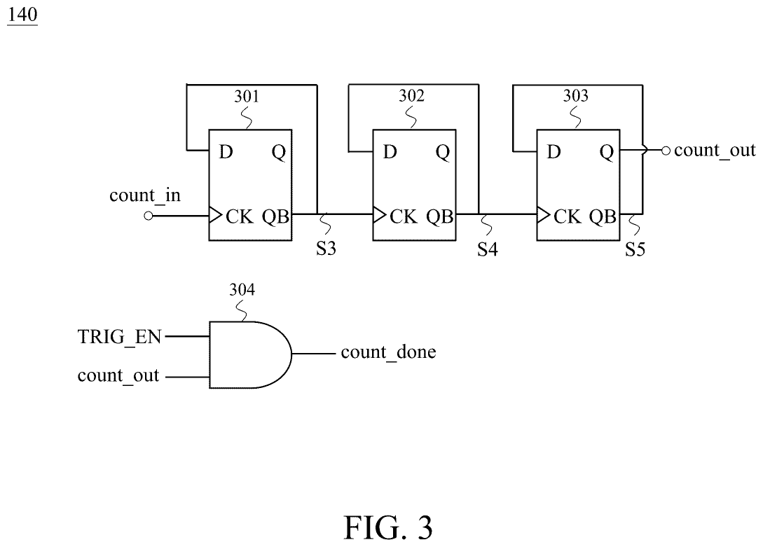

In some embodiments, the clock generator 130 is configured to generate the clock signals clkₛ, clkₐ, clkₛ, and clkₛₑ, and a counter signal count_in based on an input clock signal clk, the details of which will be described with reference to the embodiment of FIG. 2. The trigger circuit 140 is configured to, based on the counter signal count_in, generate a trigger signal count_done for use by external test equipment to probe the measured output voltage Vₜₑₛₜ of the ring amplifier 110A, the details of which will be described with reference to the embodiment of FIG. 3. More specifically, the time at a falling edge of the trigger signal count_done may indicate the time for probing the measured output voltage Vtest which has reached the maximum voltage amplitude of the output voltage Vₒᵤₜ of the ring amplifier 110A, in accordance with some embodiments.

FIG. 1B is another schematic diagram of a test system for a ring amplifier in accordance with some embodiments of the present disclosure.

The test system 100B shown in FIG. 1B may be similar to the test system 100A shown in FIG. 1A, with the difference being that the ring amplifier 110B is implemented by a continuous-time operational amplifier 111B, and a switch SW6 is added between nodes N3 and N4. The test circuit 120B, clock generator 130, and trigger circuit 140 can be collectively regarded as a measuring circuit 150B. For example, the continuous-time operational amplifier 111B is capable of processing input signals in real-time without interruption, handling signals that vary continuously over time. In some embodiments, the continuous-time operational amplifier 111B may employ continuous-time components, such as resistors, capacitors, and transistors to achieve the desired amplification and filtering characteristics. Since the continuous-time operational amplifier 111B processes input signals in real-time, resulting in that the output voltage Vₒᵤₜ generated by the continuous-time operational amplifier is continuous in all times. It should be noted that the test circuit 120B shown in FIG. 1B includes switch SW6 in addition to switch SW5 and the test capacitance Cₜₑₛₜ, compared to the test circuit 120A shown in FIG. 1A.

In some embodiments, switch S6 is controlled by the clock signal clkₐ, indicating that switch SW6 is activated (e.g. short-circuited) in response to the clock signal clkₐ being in the high logic state, and is deactivated (e.g., open-circuited) in response to the clock signal clkₐ being in the low logic state. Additionally, since the clock signals clkₛ, clkₐ, and clkₛₕₐ are non-overlapping clock signals, when then clock signal clksha is in the high logic state (e.g., switch SW5 is activated), the clock signal clka is in the low logic state (e.g., switch SW6 is deactivated), such that the test capacitance Cₜₑₛₜ can store electric charges distributed or shared from the load capacitance C_{load} at this time, indicating that the output voltage Vₒᵤₜ of the ring amplifier 110B will not affect the load voltage V_{load} at node N4 during the sharing phase.

FIG. 2 is a schematic diagram of the clock generator 130 in accordance with the embodiments of FIGS. 1A and 1B.

In some embodiments, the clock generator 130 is configured to generate the clock signals clkₛ, clkₐ, clkₛ, and clkₛₑ, and a counter signal count_in based on an input clock signal clk. For example, the clock generator 130 includes D flip-flops 201 to 204, a NOR gate 205, buffers 206 to 209, and an AND gate 210. The clock input terminal CK of the D flip-flop 201 receives the input clock signal clk, and the output signal generated at the output terminal Q of the D flip-flop 201 serves as the clock signal clk1. In some embodiments, the operating frequency of the input clock signal clk can be in a wide range from approximately 10 MHz to 10 GHz, but the present disclosure is not limited thereto.

The clock signal clk1 is sent to the NOR gate 205 and buffer 206. The clock signal clkₛₑ is obtained at the output terminal of buffer 206, and it is sent to buffer 207. The clock signal clkₛ is obtained at the output terminal of buffer 207, indicating that the clock signal clkₛₑ is a delayed version of the clock signal clk1 with a delay of buffer 206, while the clock signal clkₛ is also a delayed version of the clock signal clkₛₑ with a delay of buffer 207. It should be noted that the clock signals clkₛ and clkₛₑ can be used using the sampling phase of the ring amplifier 110A or 110B.

In some embodiments, the input data terminal D of the D flip-flop 202 receives the clock signal clk1. The clock input terminal CK of the D flip-flop 202 receives the input clock signal clk, and the output signal generated at the output terminal Q of the D flip-flop 202 serves as the clock signal clk2. The clock signal clk2 is sent to the NOR gate 205 and buffer 208. The clock signal clkₐ is obtained at the output terminal of buffer 208, indicating that the clock signal clkₐ is a delayed version of the clock signal clk2 with a delay of buffer 208. It should be noted that clock signal clkₐ can be used during the amplification phase of the ring amplifier 110A or 110B.

In some embodiments, the input data terminal D of the D flip-flop 203 receives the clock signal clk2. The clock input terminal CK of the D flip-flop 203 receives the input clock signal clk, and the output signal generated at the output terminal Q of the D flip-flop 203 serves as the clock signal clk3. The clock signal clk3 is sent to the NOR gate 205 and AND gate 210. The AND gate 210 receives the clock signal clk3 and the trigger signal count_done generated by the trigger circuit 140 to generate a signal S2 at its output terminal. The signal S2 is sent to buffer 209, and the clock signal clkₛₕₐ is obtained at the output terminal of buffer 209, indicating that the clock signal clkₛₕₐ is a delayed version of the clock signal clk3 with delays of buffer 209 and AND gate 210 when the trigger signal count_done is in the high logic state (e.g., “1”). It should be noted that clock signal clkₛₕₐ can be used during the sharing phase of the ring amplifier 110A or 110B.

In some embodiments, the input data terminal D of the D flip-flop 204 receives the clock signal clk3. The clock input terminal CK of the D flip-flop 204 receives the input clock signal clk, and the output signal generated at the inverse output terminal QB of the D flip-flop 204 serves as the counter signal count_in, which is an input signal for the trigger circuit 140 shown in FIG. 1A or FIG. 1B.

It should be noted that the NOR gate 205 receives the clock signals clk1, clk2, and clk3, and generates a signal S1, which is sent to the input data terminal D of the D flip-flop 201. This indicates that when any of the clock signals clk1, clk2, and clk3 is in the high logic state (e.g., “1”), the signal S1 generated by the NOR gate 205 is in the low logic state (e.g., “0”). For purposes of description, it is assumed that the clock signals clk1, clk2, and clk3 and the trigger signal count_in are initially in the low logic state (e.g., “0”), and the signal S1 is initially in the high logic state (e.g. “1”). Subsequently, at the rising edge of the first clock cycle of the input clock signal clk, the clock signal clk1 generated at the output terminal Q of the D flip-flop 201 transitions to the high logic state (e.g., “1”), and the clock signal clk2 generated at the output terminal Q of the D flip-flop 202 is maintained at the low logic state (e.g. “0”), and the clock signal clk3 generated at the output terminal Q of the D flip-flop 203 is also maintained at the low logic state (e.g., “0”). Additionally, the counter signal count_in transitions to the high logic state (e.g., “1”), while the signal S1 generated by the NOR gate 205 transitions to the low logic state (e.g., “0”).

At the rising edge of the second clock cycle of the input clock signal clk, the clock signal clk1 generated at the output terminal Q of the D flip-flop 201 transitions to the low logic state (e.g., “0”), and the clock signal clk2 generated at the output terminal Q of the D flip-flop 202 transitions to the high logic state (e.g. “1”), and the clock signal clk3 generated at the output terminal Q of the D flip-flop 203 is maintained at the low logic state (e.g., “0”). Additionally, the counter signal count_in is maintained at the high logic state (e.g., “1”), while the signal S1 generated by the NOR gate 205 is also maintained at the low logic state (e.g., “0”).

At the rising edge of the third clock cycle of the input clock signal clk, the clock signal clk1 generated at the output terminal Q of the D flip-flop 201 is maintained at the low logic state (e.g., “0”), and the clock signal clk2 generated at the output terminal Q of the D flip-flop 202 transitions to the low logic state (e.g. “0”), and the clock signal clk3 generated at the output terminal Q of the D flip-flop 203 transitions to the high logic state (e.g., “1”). Additionally, the counter signal count_in is maintained at the high logic state (e.g., “1”), while the signal S1 generated by the NOR gate 205 is also maintained at the low logic state (e.g., “0”).

At the rising edge of the fourth clock cycle of the input clock signal clk, the clock signal clk1 generated at the output terminal Q of the D flip-flop 201 is maintained at the low logic state (e.g., “0”), and the clock signal clk2 generated at the output terminal Q of the D flip-flop 202 is maintained the low logic state (e.g. “0”), and the clock signal clk3 generated at the output terminal Q of the D flip-flop 203 transitions to the low logic state (e.g., “0”). Additionally, the counter signal count_in transitions to the low logic state (e.g., “0”), while the signal S1 generated by the NOR gate 205 transitions to the high logic state (e.g., “1”) since the clock signals clk1, clk2, and clk3 are all in the low logic state (e.g., “0”) at this time. The operations of the clock signals clk1, clk2, and clk3, and the counter signal count_in may be repeated in a manner similar to those in the first to fourth clock cycles described above.

FIG. 3 is a schematic diagram of the trigger circuit 140 in accordance with the embodiments of FIGS. 1A and 1B.

In some embodiments, the trigger circuit 140 may be an N-bit counter, where the value of number N may be designed depending on the value of the load capacitance C_{load} and the test capacitance Cₜₑₛₜ. For purposes of description, N equals to 3 in the embodiment of FIG. 3. In some embodiments, the trigger circuit 140 includes D flip-flops 301 to 303, and an AND gate 304. The trigger circuit 140 may be configured to generate the trigger signal count_done based on the counter signal count_in generated by the clock generator 130 shown in FIG. 2.

In some embodiments, the input data terminal D of the D flip-flop 301 is coupled to its inverse output terminal QB. The clock input terminal CK of the D flip-flop 301 receives the counter signal count_in, and the output signal S3 generated at the inverse output terminal QB of the D flip-flop 301 is sent to the clock input terminal CK of the D flip-flop 302. The electrical connections of the D flip-flops 302 and 303 are similar those of the D flip-flop 301. For example, the input data terminal D of the D flip-flop 302 is coupled to its inverse output terminal QB. The clock input terminal CK of the D flip-flop 302 receives the output signal S3 generated at the inverse output terminal QB of the D flip-flop 301. Additionally, the input data terminal D of the D flip-flop 303 is coupled to its inverse output terminal QB. The clock input terminal CK of the D flip-flop 303 receives the output signal S4 generated at the inverse output terminal QB of the D flip-flop 302. The output signal generated at the output terminal Q of the D flip-flop 303 servers as the signal count_out. Furthermore, the signal count_out and a trigger enable signal TRIG_EN are sent to the AND gate 304 to generate a trigger count signal count_done.

Specifically, the output signal S3 generated at the inverse output terminal QB of the D flip-flop 301 may be inverted at each rising edge of the counter signal count_in. Similarly, the output signal S4 generated at the inverse output terminal QB of the D flip-flop 302 may be inverted at every rising edge of the output signal S3. Additionally, the output signals S5 and count_out respectively generated at the inverse output terminal QB and output terminal Q may be inverted at every rising edge of the output signal S4.

In some embodiments, based on the circuit design of the clock generator 130 shown in FIG. 2, a rising edge of the counter signal count_in occurs every four cycles of the input clock signal clk, indicating that the signal S3 generated by the D flip-flop 301 is inverted every four cycles of the input clock signal clk. Additionally, the rising edge of the output signal S3 occurs every eight cycles of the input clock signal clk, indicating that the signal S4 generated by the D flip-flop 302 is inverted every eight cycles of the input clock signal clk. Furthermore, the rising edge of the output signal S4 occurs every sixteen cycles of the input clock signal clk, indicating that the signals S5 and count_out generated by the D flip-flop 303 are inverted every sixteen cycles of the input clock signal clk.

In some embodiments, when the trigger enable signal TRIG_EN is in the high logic state (e.g., “1”), the trigger signal count_done generated by the AND gate 304 depends on the signal count_out. This indicates that the clock signal clkₛₕₐ can toggle normally when the trigger signal counter_done is in the high logic state (e.g., “1”). Additionally, when the trigger enable signal TRIG_EN is in the low logic state (e.g., “0”), the trigger signal count_done generated by the AND gate 304 is tied to the low logic state (e.g., “0”), indicating that the signal S2 generated by the AND gate 210 in FIG. 2 is tied to the low logic state (e.g., “0”), and the clock signal clkₛₕₐ is also tied to the low logic state (e.g., “0”).

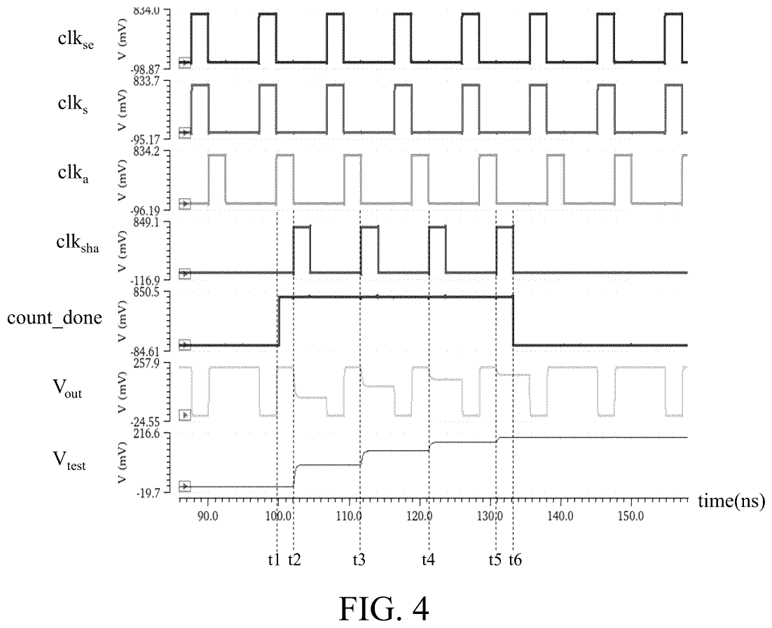

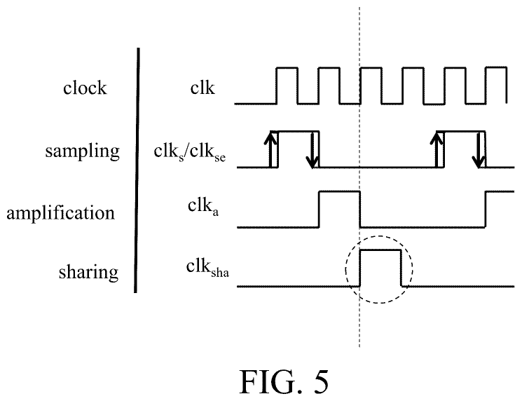

FIG. 4 is a waveform diagram of various signals within the test system in accordance with the embodiments of FIGS. 1A and 1B. FIG. 5 is a waveform diagram of different clock signals in accordance with the embodiments of FIGS. 1A and 1B. Please refer to FIGS. 1 to 5 Simultaneously.

In some embodiments, the clock signals clkₛ/clkₛₑ, clkₐ, and clkₛₕₐ may be used during the sampling phase, amplification phase, and the sharing phase, respectively, as depicted in FIG. 5. In some embodiments, as can be seen from the waveforms in FIGS. 4 and 5, the clock signals clkₛₑ and clkₛ are very similar since there is one buffer delay therebetween. Additionally, the clock signals clkₛ, clkₐ, and clkₛₕₐ are non-overlapping based on the circuit design of the clock generator 130 shown in FIG. 2. For example, during the sampling phase, switches SW1 and SW3 are activated when the clock signal clkₛ are in the high logic state (e.g., “1”), and the ring amplifier 110A or 110B can receive the input voltage signal Vᵢₙ from node NI through the sampling capacitance Cₛ. During the amplification phase, the switches SW1 and SW3 are deactivated, and switch SW2 is activated. At this time, the ring amplifier 110A or 110B can amplify the input voltage signal Vᵢₙ along the feedback path through the feedback capacitance C_{fb}, and the output voltage Vₒᵤₜ is amplified and swings. During the sharing phase, the output voltage signal Vₒᵤₜ could reach a stable voltage level when the operating frequency of the input clock signal clk is not too high. In some cases, when the operating frequency of the input clock signal clk is high, the falling edge (e.g., time t6) of the trigger signal count_done could happen before the output voltage Vₒᵤₜ reaches the stable voltage level, and the external test equipment will monitor the falling edge of the trigger signal to measure the voltage potential Vₜₑₛₜ across the test capacitance Cₜₑₛₜ.

In some embodiments, after certain clock cycles of the input clock signal clk (not shown in FIG. 4), the trigger signal count_done transitions from the low logic state (e.g. “0”) to the high logic state (e.g., “1”) at time t1. When the trigger signal count_done is in the high logic state (e.g., “1”), the clock signal clkₛₕₐ for the sharing phase of the ring amplifier 110A or 110B normally toggles, but it is still non-overlapping with the clock signals clkₛ and clkₐ. It should be noted that during the amplification phase of the ring amplifier 110A or 110B, when the clock signal clkₐ in the high logic state (e.g., “1”), the output voltage Vₒᵤₜ of the ring amplifier 110A or 110B charges the load capacitance C_{load} (i.e., switch SW6 in FIG. 1B is activated and) till the voltage potential across two terminals of the load capacitance C_{load} reaches the maximum voltage amplitude of the ring amplifier 110A or 110B.

During the sharing phase of the ring amplifier 110A or 110B, when the clock signal clkₛₕₐ in the high logic state (e.g., “1”) and clock signal clkₐ in the low logic state, the ring amplifier 110A (e.g., using the discrete-time operational amplifier 111A) does not operate, while the ring amplifier 110B continues to operate with the switch SW6 deactivated. This indicates that the output voltage Vₒᵤₜ of the ring amplifier 110A or 110B will not affect the load voltage V_{load} at node N4. Accordingly, the electric charges stored in the load capacitance C_{load} during the amplification phase can be distributed to the test capacitance Cₜₑₛₜ through the activated switch SW5 when the clock signal clkₛₕₐ is in the high logic state (e.g., “1”) (e.g., at times t2 to t5). The voltage increase of the test voltage Vₜₑₛₜ depends on the duration of the high duty of the clock signal clkₛₕₐ. As a result, the test capacitance Cₜₑₛₜ can store a portion of electric charges from the load capacitance each time the clock signal clkₛₕₐ is in the high logic state (e.g., “1”), causing the voltage potential of the test capacitance Cₜₑₛₜ to gradually increase until it reaches the maximum voltage amplitude of the ring amplifier 110A or 110B. It should be noted that an appropriate value can be selected for the number N, allowing the voltage potential of the test capacitance Cₜₑₛₜ to reach the maximum voltage amplitude of the ring amplifier 110A or 110B in N times of high logic states of the clock signal clkₛₕₐ.

In some embodiments, when the trigger signal count_done transitions from the high logic state (e.g. “1”) to the low logic state (e.g., “0”), a falling edge of the trigger signal count_done occurs, which can serve as a trigger signal to inform external test equipment to measure the test voltage Vₜₑₛₜ at node N5.

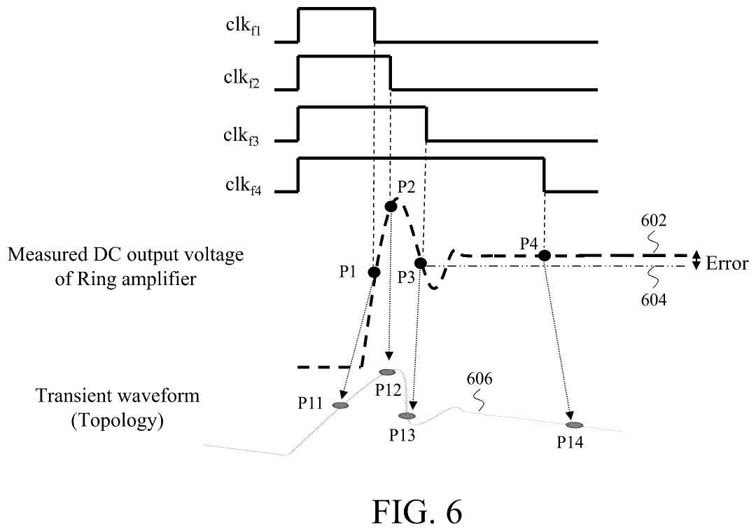

FIG. 6 is a waveform diagram illustrating the relationships between output voltage and transient waveform of the ring amplifier with respect to clock signals with different operating frequencies in accordance with some embodiments of the present disclosure.

It should be noted that because the transient waveform of the output voltage Vₒᵤₜ of the ring amplifier 110A or 110B changes very rapidly, the simulation transient waveform obtained by an electronic design automation (EDA) tool is not capable of reflecting the transient waveform (e.g., curve 606) of the output voltage Vₒᵤₜ of the ring amplifier 110A or 110B. In some embodiments, by using the test system 100A or 100B described above, the DC (direct-current) value of the output voltage Vₒᵤₜ of the ring amplifier 110A or 110B can be effectively measured by the test circuit 120A or 120B with the assistance of non-overlapping clock signals generated by the clock generator 130 given that the operating frequency of the input clock signal clk is fixed.

In some embodiments, the external test equipment is capable of adjusting the operating frequency of the input clock signal clk. For example, the four operating frequencies f1, f2, f3, and f4 of the input clock signal clk are used for illustrative purposes, and the input clock signal clk with the operating frequencies f1, f2, f3, and f4 are labeled as clk_{f1}, clk_{f2}, clk_{f3}, and clk_{f4}, as shown in FIG. 6. For example, subsequent circuitry of the ring amplifier 110A or 110B may have the specification for its input voltage, which is at the target voltage level (e.g., at point P4 on curve 602); however, the specification of the subsequent circuitry can allow an error of its input voltage within a predetermined error percentage (e.g., ±5%) without affecting the function of the subsequent circuitry. For example, when the clock signal clk_{f4} is used (e.g., lowest operating frequency), the high duty period (e.g., at high logic state of “1”) of the input clock signal clk_{f4} is long enough for the output voltage Vₒᵤₜ of the ring amplifier 110A or 110B to enter the stable voltage level (e.g., point P4 on curve 602). As the operating frequency of the input clock signal clk is gradually decreased by the external test equipment, the high-duty period of the input clock signal clk may be not long enough for the output voltage Vₒᵤₜ of the ring amplifier 110A or 110B to enter the stable voltage level (e.g., point P4 on curve 602). For example, the external test equipment may obtain the sample points P1, P2, and P3 on curve 602 using the input clock signals clk_{f1}, clk_{f2}, and clk_{f3}, respectively. It should be noted that points P1 to P4 on curve 602 may correspond to points P11 to P14 on curve 606.

In some embodiments, the voltage level of the output voltage Vₒᵤₜ of the ring amplifier 110A or 110B measured by the test circuit 120A or 120B may be converted to a corresponding digital value by an analog-to-digital converter (ADC) within the external test equipment. For example, the voltage level of the output voltage Vₒᵤₜ at point P3 may be within the predetermined error percentage of the target voltage level (e.g., at point P4), while the voltage level of the output voltage Vₒᵤₜ at point P1 or P2 may exceed the predetermined error percentage of the target voltage level (e.g., at point P4). Accordingly, it indicates that input clock signal clkf3 can be applied to the ring amplifier 110A or 110B, thereby achieving a higher performance of the ring amplifier 110A or 110B and complying with the specification of the subsequent circuitry without affecting its function.

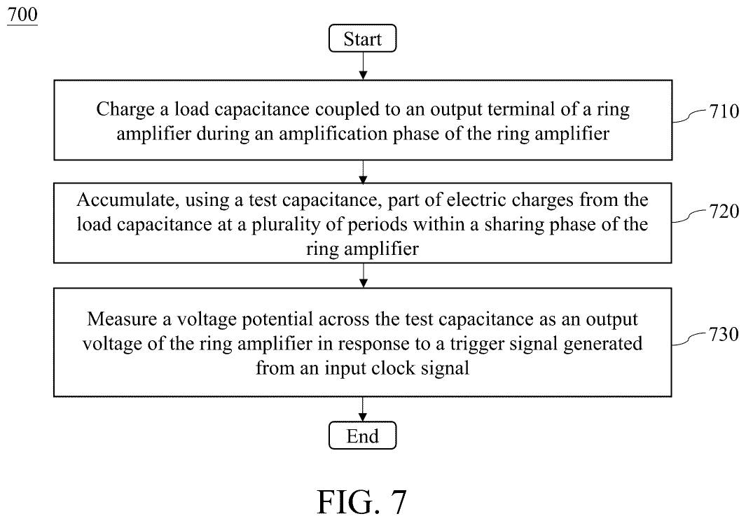

FIG. 7 is a flowchart of a method for operating a measuring circuit for a ring amplifier in accordance with some embodiments of the present disclosure. The method 700 includes operations 710 to 730. Please refer to FIGS. 1 to 3 and FIG. 7 simultaneously.

At operation 710, charge a load capacitance coupled to an output terminal of a ring amplifier during an amplification phase of the ring amplifier. In some embodiments, the ring amplifier 110A or 110B shown in FIG. 1A or 1B may have multiple operational phases, such as a sampling phase, an amplification phase, and a sharing phase. During the amplification phase, the load capacitance C_{load} is charged by the output voltage Vₒᵤₜ at the output terminal (e.g., node N3) of the ring amplifier 110A or 110B.

At operation 720, accumulate, using a test capacitance; part of electric charges from the load capacitance at a plurality of periods within a sharing phase of the ring amplifier. In some embodiments, the test capacitance Cₜₑₛₜ is electrically disconnected from the load capacitance C_{load} during the amplification phase of the ring amplifier 110A or 110B without affecting the operations of the ring amplifier 110A or 110B. The test capacitance Cₜₑₛₜ is electrically connected to the load capacitance C_{load} through switch SW5 controlled by the clock signal clkₛₕₐ.

At operation 730, measure a voltage potential across the test capacitance as an output voltage of the ring amplifier in response to a trigger signal generated from an input clock signal. In some embodiments, the clock generator 130 is configured to generate the counter signal count_in, which serves as the input signal of the trigger circuit 140. The trigger circuit 140 utilizes a plurality of D flip-flops 301 to 303 arranged in a DFF chain to generate the signal count_out. The AND gate 304 may receive the trigger enable signal TRIG_EN and the signal count_out to generate the trigger signal count_done, which can be used to indicate the sharing phase of the ring amplifier 110A or 110B. Upon a falling edge of the trigger signal count_done, the external test equipment can measure the voltage potential Vₜₑₛₜ across the test capacitance Cₜₑₛₜ to obtain the voltage level of the ring amplifier 110A or 110B.

An aspect of the present disclosure provides a measuring circuit which includes a clock generator, a test circuit, and a trigger circuit. The clock generator is configured to convert an input clock signal into a plurality of clock signals, which are non-overlapping, and generate a counter signal. The test circuit is coupled to an output terminal of a ring amplifier and is configured to store electric charges from a load capacitance of the ring amplifier using a test capacitance. The trigger circuit is configured to generate a trigger signal for measuring an output voltage of the ring amplifier based on the counter signal.

Another aspect of the present disclosure provides a measuring circuit which includes a clock generator, a test circuit, and a trigger circuit. The clock generator is configured to convert an input clock signal into a plurality of clock signals and generate a counter signal. The test circuit is coupled to an output terminal of a ring amplifier and is configured to accumulate a voltage potential across a test capacitance, which is coupled to a load capacitance of the ring amplifier through a first switch, at a plurality of periods within a sharing phase of the ring amplifier. The trigger circuit is configured to generate a trigger signal for measuring an output voltage of the ring amplifier based on the counter signal.

Yet another aspect of the present disclosure provides a method, which includes the following steps: charging a load capacitance coupled to an output terminal of a ring amplifier during an amplification phase of the ring amplifier; accumulating, using a test capacitance, part of electric charges from the load capacitance at a plurality of periods within a sharing phase of the ring amplifier; and measuring a voltage potential across the test capacitance as an output voltage of the ring amplifier in response to a trigger signal generated from an input clock signal.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A measuring circuit, comprising:
a clock generator, configured to convert an input clock signal into a plurality of clock signals, which are non-overlapping, and generate a counter signal;
a test circuit, coupled to an output terminal of a ring amplifier, and configured to store electric charges from a load capacitance of the ring amplifier using a test capacitance; and
a trigger circuit, configured to generate a trigger signal for measuring an output voltage of the ring amplifier based on the counter signal.

2. The measuring circuit of claim 1, wherein the plurality of clock signals comprise a first clock signal, a second clock signal, and a third clock signal, that are used during a sampling phase, an amplification phase, the sampling phase, and a sharing phase of the ring amplifier, respectively.

3. The measuring circuit of claim 2, wherein the load capacitance is coupled to the output terminal of the ring amplifier, and is charged by the output voltage of the ring amplifier during the amplification phase.

4. The measuring circuit of claim 3, wherein the test circuit comprises:
a first switch, coupled between the output terminal and a first node, and activatable by the third clock signal generated by the clock generator; and
the test capacitance, coupled between the first node and a ground.

5. The measuring circuit of claim 4, wherein the clock generator comprises:
a first D flip-flop, having a clock input terminal receiving the input clock signal, a data input terminal receiving a first signal, a data output terminal outputting a first intermediate clock signal;
a second D flip-flop, having a clock input terminal receiving the input clock signal, a data input terminal receiving the first intermediate clock signal, a data output terminal outputting a second intermediate clock signal;
a third D flip-flop, having a clock input terminal receiving the input clock signal, a data input terminal receiving the second intermediate clock signal, a data output terminal outputting a third intermediate clock signal;
a fourth D flip-flop, having a clock input terminal receiving the input clock signal, a data input terminal receiving the third intermediate clock signal, an inverse data output terminal outputting the counter signal; and
a NOR gate, configured to receive the first intermediate clock signal, the second intermediate clock signal, and the third intermediate clock signal to generate the first signal.

6. The measuring circuit of claim 5, wherein the clock generator further comprises:
a first buffer, configured to receive the first intermediate clock signal to generate a fourth clock signal;
a second buffer, configured to receive the fourth clock signal to generate the first clock signal;
a third buffer, configured to receive the second intermediate clock signal to generate the second clock signal;
an AND gate, configured to receive the third intermediate clock signal and the trigger signal to generate a second signal; and
a fourth buffer, configured to receive the second signal to generate the fourth clock signal.

7. The measuring circuit of claim 5, wherein the trigger circuit comprises:
a fifth D flip-flop, having a clock input terminal receiving the counter signal, a data input terminal receiving a third signal, and an inverse data output terminal outputting the third signal;
a sixth D flip-flop, having a clock input terminal receiving the third signal, a data input terminal receiving a fourth signal, and an inverse data output terminal outputting the fourth signal;
a seventh D flip-flop, having a clock input terminal receiving the fourth signal, a data input terminal receiving a fifth signal, an inverse data output terminal outputting the fifth signal, and a data output terminal outputting a counter output signal; and
an AND gate, configured to receive a trigger enable signal and the counter output signal to generate the trigger signal.

8. The measuring circuit of claim 4, wherein in response to the trigger signal and the third clock signal being in a high logic state during the sharing phase, the first switch is activated, and the test capacitance stores part of the electric charges from the load capacitance until a voltage potential across the test capacitance reaches a maximum voltage amplitude of the ring amplifier.

9. The measuring circuit of claim 8, wherein the ring amplifier comprises an operational amplifier having a first input terminal coupled to the output terminal of the ring amplifier through a feedback capacitance, and a second input terminal being grounded.

10. The measuring circuit of claim 9, wherein the operational amplifier is implemented using a discrete-time operational amplifier.

11. The measuring circuit of claim 9, wherein the test circuit further comprises: a second switch coupled between the load capacitance and the output terminal of the ring amplifier, wherein the second switch is activatable by the second clock signal.

12. The measuring circuit of claim 11, wherein the ring amplifier comprises a continuous-time operational amplifier.

13. The measuring circuit of claim 4, wherein in response to a falling edge of the trigger signal, the output voltage of the ring amplifier is measured by external test equipment at the first node.

14. A measuring circuit, comprising:
a clock generator, configured to convert an input clock signal into a plurality of clock signals and generate a counter signal;
a test circuit, coupled to an output terminal of a ring amplifier, and configured to accumulate a voltage potential across a test capacitance, coupled to a load capacitance of the ring amplifier through a first switch, at a plurality of periods within a sharing phase of the ring amplifier; and
a trigger circuit, configured to generate a trigger signal for measuring an output voltage of the ring amplifier based on the counter signal.

15. The measuring circuit of claim 14, wherein:
the load capacitance is coupled to the output terminal of the ring amplifier, and is charged by the output voltage of the ring amplifier during the amplification phase;
the plurality of clock signals comprises a first clock signal, a second clock signal, a third clock signal, and a fourth clock signal, that are used during a sampling phase, an amplification phase, the sampling phase, the sharing phase, and the sampling phase of the ring amplifier, respectively; and
the first clock signal, the second clock signal, and the third clock signal are non-overlapping.

16. The measuring circuit of claim 15, wherein the test circuit comprises:
the first switch, coupled between the output terminal and a first node, and activatable by the third clock signal generated by the clock generator; and
the test capacitance, coupled between the first node and a ground.

17. The measuring circuit of claim 16, wherein the test circuit further comprises: a second switch coupled between the load capacitance and the output terminal of the ring amplifier, wherein the second switch is activatable by the second clock signal.

18. The measuring circuit of claim 17, wherein the ring amplifier comprises a continuous-time operational amplifier.

19. A method, comprising:
charging a load capacitance coupled to an output terminal of a ring amplifier during an amplification phase of the ring amplifier;
accumulating, using a test capacitance, part of electric charges from the load capacitance at a plurality of periods within a sharing phase of the ring amplifier; and
measuring a voltage potential across the test capacitance as an output voltage of the ring amplifier in response to a trigger signal generated from an input clock signal.

20. The method of claim 19, further comprising:
disconnecting the test capacitance from the load capacitance during the amplification phase; and
connecting the test capacitance to the load capacitance during the sharing phase.
